(19) United States
(12) Patent Application Publication
(10) Pub. No.: US 2013/0169374 A1
(43) Pub. Date: Jul. 4, 2013

(54) VOLTAGE CONTROLLED OSCILLATOR

(71) Applicants: Zhe-Yang HUANG, TAOYUAN COUNTY (TW); Chung-Chih HUNG, TAINAN CITY (TW)

(72) Inventors: Zhe-Yang HUANG, TAOYUAN COUNTY (TW); Chung-Chih HUNG, TAINAN CITY (TW)

(73) Assignee: INDUSTRIAL TECHNOLOGY RESEARCH INSTITUTE, HSINCHU (TW)

(21) Appl. No.: 13/598,535

(22) Filed: Aug. 29, 2012

(30) Foreign Application Priority Data
Dec. 29, 2011 (TW) TW100149459

(51) Int. Cl. H03B 5/12

(52) U.S. Cl. 331/117 FE

(57) ABSTRACT

Voltage controlled oscillators are disclosed. The voltage controlled oscillator includes an inductive circuit, a cross-coupled N-type transistor pair, and a cross-coupled P-type transistor pair. The inductive circuit includes two inductive windings stacked together, and is configured to generate a pair of differential resonance signals. The cross-coupled N-type transistor pair is coupled in series with the inductive circuit, and configured to receive the pair of differential resonance signals to generate a first oscillation signal. The cross-coupled P-type transistor pair is coupled in series with the inductive circuit, and configured to receive the pair of differential resonance signals to generate a second oscillation signal. The first oscillation signal and second oscillation signal include substantially the same frequency and are out-of-phase to each other. The first oscillation and second oscillation signal have substantially the same frequency which is twice that of the pair of the differential resonance signals.

### CROSS REFERENCE TO RELATED APPLICATIONS

This application claims priority of Taiwan Patent Application No. 100149459, filed on Dec. 29, 2011, and the entirety of which is incorporated by reference herein.

### BACKGROUND

1. Technical Field

The present disclosure relates to electronic circuits, and in particular relates to a voltage controlled oscillator.

2. Related Art

As wireless communication technology advances, high-frequency transmission is being applied in various fields such as Wireless Personal Area Network (WPAN) operating at a wide? frequency range between 57.24 GHz and 65.88 GHz. Complementary Metal Oxide Semiconductor (CMOS) technology is used to implement high-frequency microwave circuits.

### SUMMARY

In one aspect of the disclosure, a voltage controlled oscillator is disclosed, comprising an inductive circuit, a cross-coupled N-type transistor pair, and a cross-coupled P-type transistor pair. The inductive circuit is configured to generate a pair of differential resonance signals. The cross-coupled N-type transistor pair is coupled in series with the inductive circuit, and configured to receive the pair of differential resonance signals to generate a first oscillation signal. The cross-coupled P-type transistor pair is coupled in series with the inductive circuit, configured to receive the pair of differential resonance signals to generate a second oscillation signal. The first oscillation signal and second oscillation signal comprise substantially the same frequency and are out-of-phase to each other. The first oscillation and second oscillation signal have substantially the same frequency which is twice that of the pair of the differential resonance signals.

In another aspect of the disclosure, a voltage controlled oscillator is provided, comprising an inductive circuit and a cross-coupled N-type transistor pair. The inductive circuit comprises two inductive windings stacked together, and is configured to generate a pair of differential resonance signals. The cross-coupled N-type transistor pair is coupled in series with the inductive circuit, and configured to receive the pair of differential resonance signals to generate a first oscillation signal. The first oscillation signal has a frequency which is twice that of the pair of the differential resonance signals.

In another aspect of the disclosure, a voltage controlled oscillator is taught, comprising an inductive circuit, a cross-coupled N-type transistor pair, and a cross-coupled P-type transistor pair. The inductive circuit comprises two inductive windings stacked together, and is configured to generate a pair of differential resonance signals. The cross-coupled N-type transistor pair is coupled in series with the inductive circuit, and configured to receive the pair of differential resonance signals to generate a first oscillation signal. The cross-coupled P-type transistor pair is coupled in series with the inductive circuit, configured to receive the pair of differential resonance signals to generate a second oscillation signal. The first oscillation signal and second oscillation signal comprise substantially the same frequency and are out-of-phase to each other. The first oscillation and second oscillation signal have substantially the same frequency which is twice that of the pair of the differential resonance signals.

### BRIEF DESCRIPTION OF DRAWINGS

The embodiment can be more fully understood by reading the subsequent detailed description and examples with references made to the accompanying drawings, wherein:

FIG. 1 is a block diagram of a transceiver 1 according to an embodiment;

FIG. 2 is a circuit schematic of a voltage controlled oscillator 2 according to an embodiment;

FIG. 3 is a circuit schematic of a voltage controlled oscillator 3 according to an embodiment; and

FIG. 4 is a circuit schematic of a voltage controlled oscillator 4 according to another embodiment.

### DETAILED DESCRIPTION

A detailed description is given in the following embodiments with reference to the accompanying drawings.

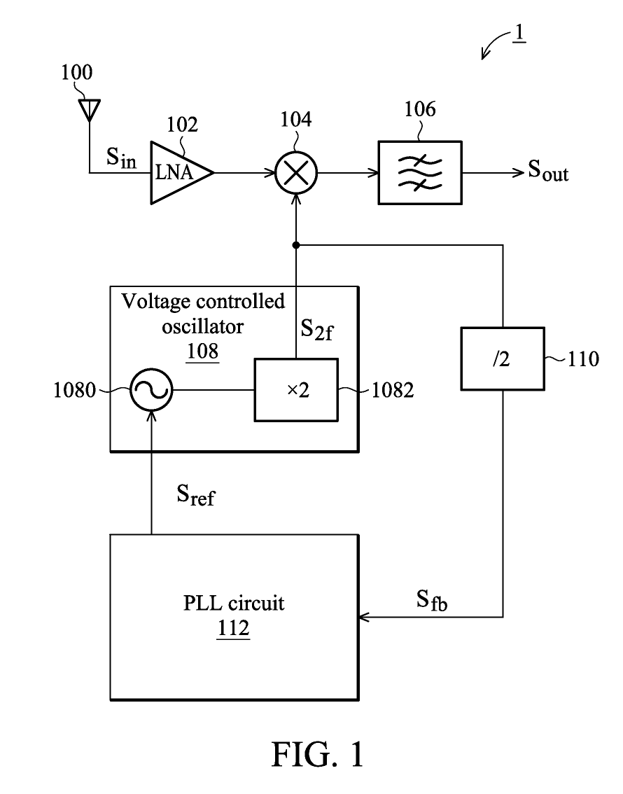

FIG. 1 is a block diagram of a transceiver 1 according to an embodiment, comprising an antenna 100, a Low Noise Amplifier (LNA) 102, a demodulator 104, a band-pass filter 106, a voltage controlled oscillator 108, a frequency divider 110, and a Phase Locked Loop (PLL) circuit 112. The antenna 100 is coupled to the LNA 102, the demodulator 104, the band-pass filter 106. The voltage controlled oscillator 108, the frequency divider 110, and the PLL circuit 112 form a loop. The voltage-controlled oscillator 108 is coupled to the demodulator 104.

Once the antenna 100 detects an Radio Frequency (RF) input signal Sᵢₙ from an air interface, the LNA 102 may amplify the RF input signal Sin, and if so, the demodulator 104 demodulates the amplified signal with a demodulation signal S2f, and the band-pass filter 106 filters out noise from the demodulated signal to generate an intermediate-frequency (IF) or baseband output signal Sₒᵤₜ. Since The input signal Sᵢₙ may be in a high frequency such as 60 GHz, the voltage controlled oscillator 108 may generate a signal in a frequency such as 24 GHz, which is then doubled in frequency to output a higher-frequency signal S2f in a higher frequency such as 48 GHz. In an embodiment, the 12 GHz demodulated signal Sₒᵤₜ may be brought to a baseband frequency by an oscillation signal in 12 GHz (not shown).

Orthogonal Frequency Division Multiplexing (OFDM) technology and differential technology have been widely adopted for many communications networks, and other transmission protocols. As a consequence, orthogonal signals with 90-degree difference in phases and differential signals with 180-degree difference in phases are frequently used in transmitters and receivers. A voltage controlled oscillator 108, with differential or orthogonal signaling outputs is provided in the embodiment, incorporating a noise cancellation technology provided by magnetically coupling inductors, without a need for an add-on circuit, increasing performance thereof.

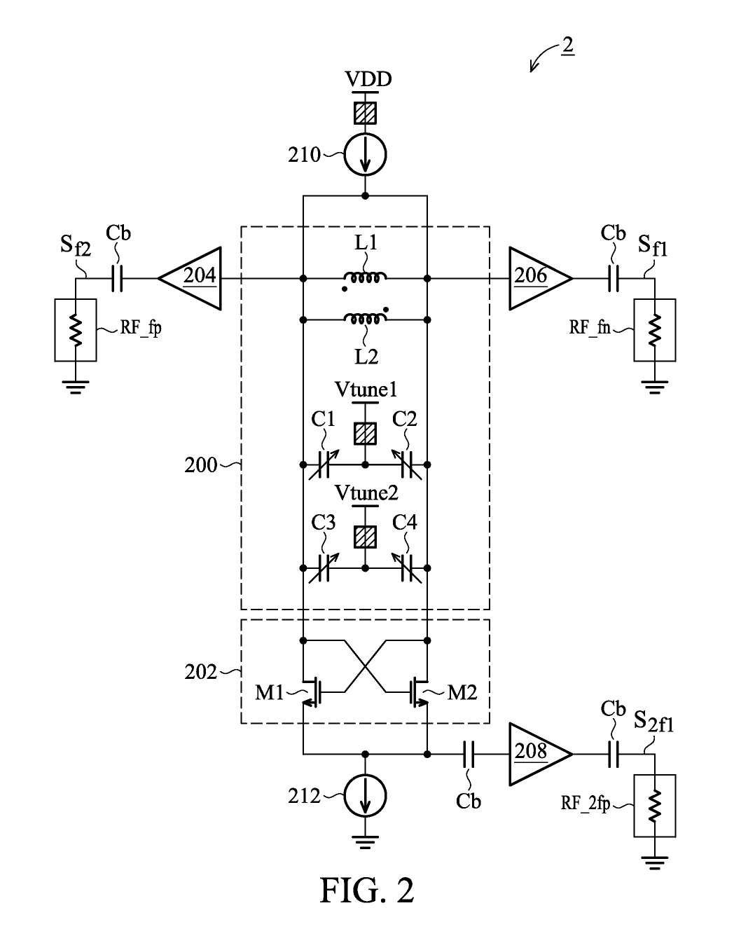

FIG. 2 is a circuit schematic of a voltage controlled oscillator 2 according to an embodiment, comprising an LC oscillator (inductive circuit) 200, an NMOS cross-coupled pair (N-type crossed-coupled pair) 202, buffers 204, 206, and 208, and current sources 210 and 212. The voltage controlled oscillator 2 may be implemented in the transceiver 1 in FIG. 1. The LC oscillator 200 is coupled in series to the NMOS cross-coupled pair 202, and outputs a pair of differential oscillation signals S_{f1} and S_{f2} to further generate a double-frequency signal S2f with substantially twice the frequency of the differential oscillation signals. The pair of differential oscillation signals S_{f1} and S_{f2} is out-of-phase to each other. For example, the pair of differential oscillation signals S_{f1} and S_{f2} are 24 GHz in frequency, and the double-frequency signal S2f is 24 GHz. The pair of differential oscillation signals S_{f1} and S_{f2} and the double-frequency signal S_{2f} may be utilized in a transmitter or a receiver for modulating or demodulating a transmission signal.

The LC oscillator 200 comprises two stacked windings L1 and L2 magnetically coupled to each other, through which magnetic flux are combined to increase inductance thereof. In comparison to a single inductive winding, the inductive windings L1 and L2 increase a quality factor thereof, providing wider bandwidth for a usable quality factor, capable of noise cancellation to accommodate noise suppression. In some embodiments, the voltage controlled oscillator 2 is implemented by an integrated circuit, and the two inductive windings L1 and L2 occupy substantially a same area on the integrated circuit, and are realized on different layers of the integrated circuit. For example, the inductive winding L1 occupies the fifth and sixth layer and the inductive winding L2 occupies the fourth and fifth layers on the integrated circuit. By interwinding with each other, the inductive windings L1 and L2 are stacked onto each other. In other embodiments, the inductive winding L1 occupies the sixth layer and the inductive winding occupies the fifth layer of the integrated circuit, wherein the inductive windings L1 and L2 are stacked together, with the inductive winding L1 being placed directly on the top of the inductive winding L2. In some implementations, the inductive windings L1 and L2 are realized by microstrips. In some implementations, the inductive windings L1 and L2 comprise substantially a same inductance and a same number of turns. In other implementations, the inductive windings L1 and L2 comprise different inductances and different numbers of turns.

LC oscillator 200 may further include variable capacitors C1, C2, C3, and C4 with capacitances adjustable by adjustment signals Vtune1 and Vtune2, thereby changing an LC resonance frequency of the LC oscillator 200, which falls in the middle of the transmission frequencies. In some embodiments, the variable capacitors C1, C2, C3, and C4 may be realized by pass-gates, MOS varactor capacitors or varactor diodes. The LC resonance frequency is defined by the inductance of the inductive windings and capacitances of the variable capacitors, rendering the oscillation frequency for the signals S_{f1} and S_{f2}. In practice, the LC oscillator 200 has an internal parasitic loss, causing the energy in the LC oscillator to decrease with time. Thus, the NMOS cross-coupled pair 202 in the voltage controlled oscillator 2 inputs a constant power into the LC oscillator 200, maintaining the resonance energy of the LC oscillation.

The NMOS cross-coupled pair 202 may comprise two NMOS transistors M1 and M2. The NMOS cross-coupled pair 202 provides a negative resistance (small signal) to cancel out the resistance in the LC oscillator 200. Moreover, the NMOS cross-coupled pair 202 also produces the double-frequency signal S_{2f} with twice the frequency of that of the differential oscillation signals S_{f1} and S_{f2}. The NMOS cross-coupled pair 202 contains a negative transconductance which produces negative resistance to cancel the parasitic resistance in the LC oscillator 200, and compensates for the losses in the LC oscillator 200.

In some embodiments, the voltage controlled oscillator 2 further comprises a PMOS cross-coupled pair (Cross-coupled P-type pair) (not shown). The PMOS cross-coupled par is coupled in series to the LC oscillator 200, generating a second double-frequency signal according to the differential oscillation signals S_{f1} and S_{f2}. The second double-frequency signal and the double-frequency signal S_{2f} are substantially out-of-phase to each other. When the device size of the PMOS cross-coupled pair are 5 to 7 times that of the NMOS cross-coupled pair 202, the voltage controlled oscillator 2 is optimized for generating the oscillation signals with decreased noise.

The bias current sources 210 and 212 provide a fixed biased current to the LC oscillator 200 and the NMOS cross-coupled pair 202, thereby controlling the output powers and the phase noises of the output oscillation signals S_{f1}, S_{f2}, and S_{2f}. The bias current sources 210 and 212 may be realized by NMOS transistors.

The buffers 204, 206, and 208 respectively receive and reinforce the oscillation signals produced by the LC oscillator 200 and the NMOS cross-coupled pair 202, wherein outputs thereof pass through the filter capacitor Cb to generate the oscillation signal S_{f1} and S_{f2} and the double-frequency oscillation signal S_{2f}.

The embodiments in FIG. 2 utilizes two stacked inductors magnetically coupled to each other, resulting in noise cancellation, increasing the quality factor and the usable bandwidth, thereby increasing performance of the voltage controlled oscillator.

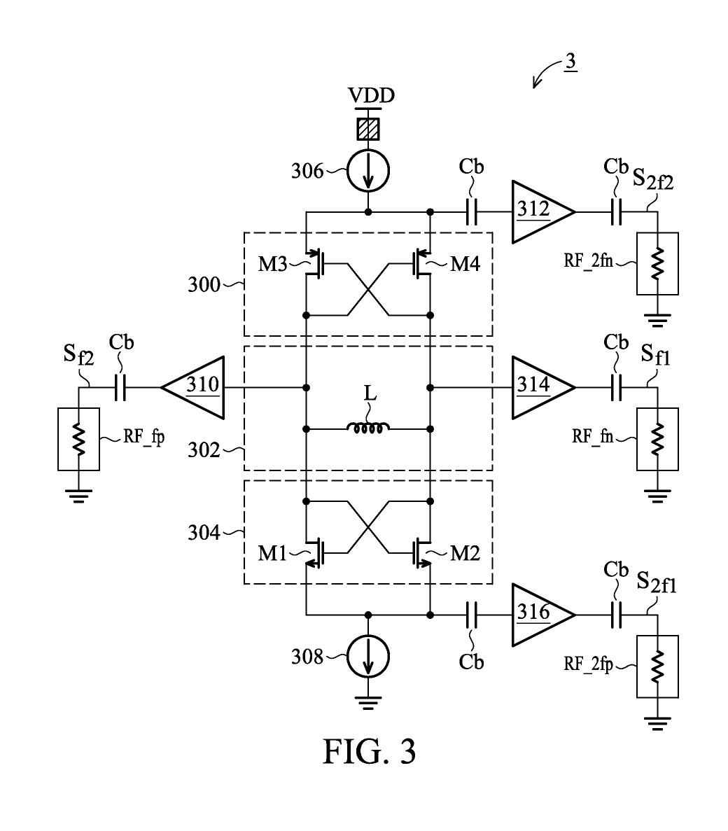

FIG. 3 is a circuit schematic of a voltage controlled oscillator 3 according to an embodiment, comprising a PMOS cross-coupled pair (Cross-coupled P-type pair) 300, an LC oscillator (inductive circuit) 302, an NMOS cross-coupled pair (Cross-coupled N-type pair) 304, buffers 310, 312, 314, and 316, and current sources 306 and 308. The PMOS cross-coupled pair is coupled in series to the LC oscillator 302 which is further coupled in series to the NMOS cross-coupled pair 304. The LC oscillator 302 is coupled in series to the PMOS cross-coupled pair 300 and the NMOS cross-coupled pair 304, and outputs a pair of differential oscillation signals S_{f1} and S_{f2} to produce a first and a second double-frequency oscillation signals S_{2f1} and S_{2f2}. The first and second double-frequency oscillation signals operates in substantially a same frequency with an out-of-phase relationship to each other, wherein the operation frequency thereof is substantially twice that of the pair of differential oscillation signals S_{f1} and S_{f2}.

The circuit configuration and operation of the PMOS cross-coupled pair 300 and the NMOS cross-coupled pair 304 are identical to those of the PMOS cross-coupled pair and the NMOS cross-coupled pair 204 in FIG. 2, wherein the buffers 310, 312, 314 and 316 are identical to buffers 204, 206, and 208, and the current sources 306 and 308 are identical to current sources 210 and 212. Thus, since reference can be made to preceding paragraphs, explanation therefore will not be repeated here.

The LC oscillator 302 may be any circuit capable of producing oscillation signals, and may comprise an inductor, a capacitor, or a resistor. In some embodiments, the oscillator 302 comprises an inductor, coupled across the PMOS cross-coupled pair M3 and M4 and the NMOS cross-coupled pair M1 and M2. In other embodiments, the LC oscillator 302 comprises two inductors, wherein one is coupled in series to the transistors M3 and M1, and the other is coupled in series to the transistors M4 and M2. In yet other embodiments, the LC oscillator 302 comprises one or more variable capacitor adjusting an LC resonance frequency of the LC oscillator 302. For realizing the operation of the variable capacitors, reference may be found in the preceding paragraphs for the capacitors C1, C2, C3, and C4 in FIG. 2.

The embodiment in FIG. 3 utilizes a frequency-doubled voltage controlled oscillator with differential outputs, without a need for an add-on circuit, in combination with the magnetically coupled inductors to provide the noise cancellation, increasing performance of the voltage controlled oscillator.

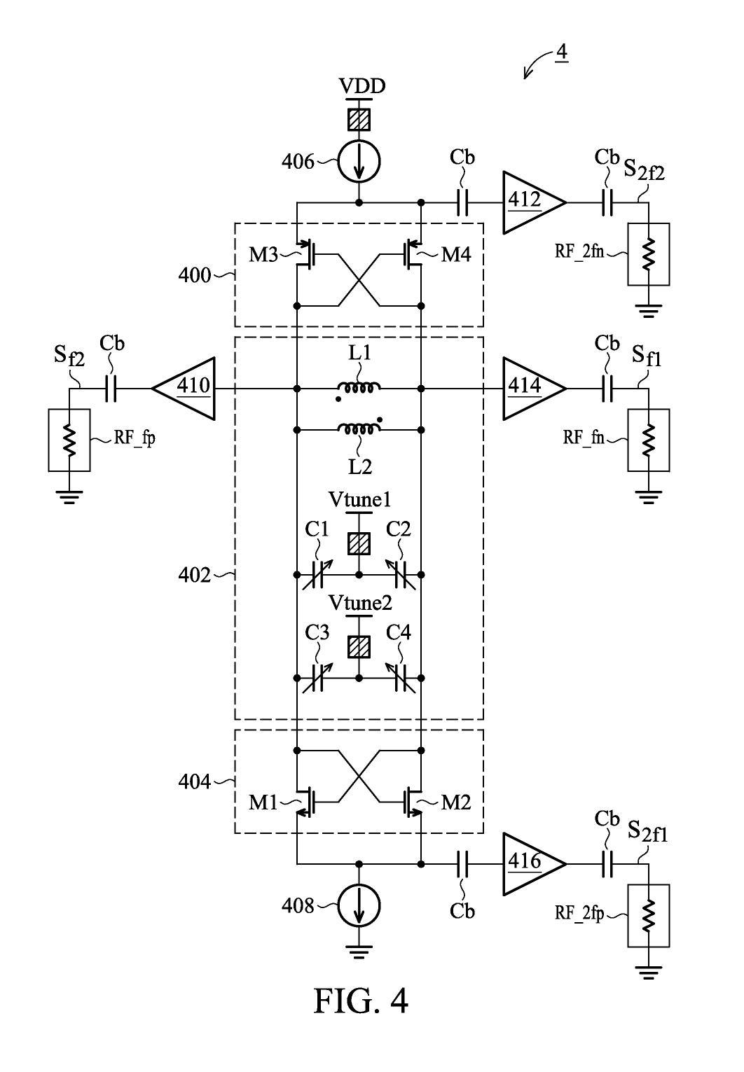

FIG. 4 is a circuit schematic of a voltage controlled oscillator 4 according to another embodiment, comprising a PMOS cross-coupled pair (Cross-coupled P-type pair) 400, an LC oscillator (inductive circuit) 402, an NMOS cross-coupled pair (Cross-coupled N-type pair) 404, buffers 410, 412, 414, and 416, and current sources 406 and 408. The PMOS cross-coupled pair is coupled in series to the LC oscillator 402 which is further coupled in series to the NMOS cross-coupled pair 404. The LC oscillator 402 is coupled in series to the PMOS cross-coupled pair 400 and the NMOS cross-coupled pair 404, and outputs a pair of differential oscillation signals S_{f1} and S_{f2} to produce a first and a second double-frequency oscillation signals S_{2f1} and S_{2f2}. The first and second double-frequency oscillation signals operates in substantially a same frequency with an out-of-phase relationship to each other, the operation frequency thereof is substantially twice that of the pair of differential oscillation signals S_{f1} and S_{f2}.

The circuit configuration and operation of the PMOS cross-coupled pair 400 the NOS cross-coupled pair 404 are identical to those of the PMOS cross-coupled pair and the NOS cross-coupled pair 204 in FIG. 2, and the buffers 410, 412, 414 and 416 are identical to buffers 204, 206, and 208, and the current sources 406 and 408 are identical to current sources 210 and 212. Thus, since reference can be made to preceding paragraphs, explanation therefore will not be repeated here.

The LC oscillator 402 comprises two inductive windings L1 and L2 configured such that the magnetic flux induced by the windings L1 and L2 can be combined to increase the inductance of the inductive windings L1 and L2.

The embodiment in FIG. 4 utilizes a frequency-doubled voltage controlled oscillator with differential outputs, without a need for an add-on circuit, in combination with the magnetically coupled inductors to provide noise cancellation, increasing performance of the voltage controlled oscillator.

As used herein, the term “determining” encompasses calculating, computing, processing, deriving, investigating, looking up (e.g., looking up in a table, a database or another data structure), ascertaining and the like. Also, “determining” may include resolving, selecting, choosing, establishing and the like.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A voltage controlled oscillator, comprising:
an inductive circuit, configured to generate a pair of differential resonance signals;
a cross-coupled N-type transistor pair, coupled in series with the inductive circuit, configured to receive the pair of differential resonance signals to generate a first oscillation signal; and
a cross-coupled P-type transistor pair, coupled in series with the inductive circuit, configured to receive the pair of differential resonance signals to generate a second oscillation signal,
wherein the first oscillation signal and second oscillation signal comprise substantially the same frequency and are out-of-phase to each other; and
the first oscillation and second oscillation signal have substantially the same frequency which is twice that of the pair of the differential resonance signals.

2. The voltage controlled oscillator of claim 1, wherein the inductive circuit comprises a pair of inductors magnetically coupled to each other.

3. The voltage controlled oscillator of claim 1, wherein the inductive circuit comprises two inductors stacked together.

4. The voltage controlled oscillator of claim 1, wherein the inductive circuit comprises a variable capacitor adaptable to change a frequency of the pair of differential resonance signals.

5. The voltage controlled oscillator of claim 1, wherein a device size of the cross-coupled P-type pair is substantially 5 to 7 times that of the cross-coupled N-type pair.

6. The voltage controlled oscillator of claim 1, further comprising:
a first transistor, configured to provide a first bias current to the cross-coupled N-type pair to generate the first oscillation signal; and
a second transistor, configured to provide a first bias current to the cross-coupled P-type pair to generate the second oscillation signal.

7. A voltage controlled oscillator, comprising:
an inductive circuit, comprising two inductive windings stacked together, and configured to generate a pair of differential resonance signals; and
a cross-coupled N-type transistor pair, coupled in series with the inductive circuit, configured to receive the pair of differential resonance signals to generate a first oscillation signal,
wherein the first oscillation signal has a frequency which is twice that of the pair of the differential resonance signals.

8. The voltage controlled oscillator of claim 7, wherein the two inductive windings are magnetically coupled to each other.

9. The voltage controlled oscillator of claim 7, wherein the two inductive windings occupy substantially a same area on an integrated circuit, and are implemented on different layers of the integrated circuit.

10. The voltage controlled oscillator of claim 7, wherein the inductive circuit comprises a variable capacitor adaptable to change a frequency of the pair of differential signals.

11. The voltage controlled oscillator of claim 7, further comprising:
a cross-coupled P-type transistor pair, coupled in series with the inductive circuit, configured to receive the pair of differential resonance signals to generate a second oscillation signal,
wherein the first oscillation and second oscillation signal comprise substantially a same frequency and are out-of-phase to each other.

12. The voltage controlled oscillator of claim 11, wherein a device size of the cross-coupled P-type pair exceeds that of the cross-coupled N-type pair.

13. The voltage controlled oscillator of claim 11, wherein a device size of the cross-coupled P-type pair is substantially 5 to 7 times that of the cross-coupled N-type pair.

14. The voltage controlled oscillator of claim 1, further comprising:
a first transistor, configured to provide a first bias current to the cross-coupled N-type pair to generate the first oscillation signal; and
a second transistor, configured to provide a first bias current to the cross-coupled P-type pair to generate the second oscillation signal.

15. A voltage controlled oscillator, comprising:
an inductive circuit, comprising two inductive windings stacked together, and configured to generate a pair of differential resonance signals;
a cross-coupled N-type transistor pair, coupled in series with the inductive circuit, configured to receive the pair of differential resonance signals to generate a first oscillation signal; and
a cross-coupled P-type transistor pair, coupled in series with the inductive circuit, configured to receive the pair of differential resonance signals to generate a second oscillation signal,
wherein the first oscillation and second oscillation signal comprise substantially the same frequency and are out-of-phase to each other; and
the first oscillation and second oscillation signal have substantially the same frequency which is twice that of the pair of the differential resonance signals.

16. The voltage controlled oscillator of claim 15, wherein the inductive windings are magnetically coupled to each other.

17. The voltage controlled oscillator of claim 15, wherein the inductive circuit comprises a variable capacitor adaptable to change a frequency of the pair of differential resonance signals.

18. The voltage controlled oscillator of claim 15, wherein a device size of the Cross-coupled P-type pair is substantially 5 to 7 times that of the cross-coupled N-type pair.

19. The voltage controlled oscillator of claim 1, further comprising:
a first transistor, configured to provide a first bias current to the cross-coupled N-type pair to generate the first oscillation signal; and
a second transistor, configured to provide a first bias current to the cross-coupled P-type pair to generate the second oscillation signal.

20. The voltage controlled oscillator of claim 15, wherein the two inductive windings occupy substantially a same area on an integrated circuit, and are implemented on different layers of the integrated circuit.
